(19) United States
(12) Patent Application Publication
(10) Pub. No.: US 2015/0123262 A1
(43) Pub. Date: May 7, 2015

(54) POWER SEMICONDUCTOR CLAMPING STACK

(71) Applicant: ABB TECHNOLOGY AG, Zurich (CH)

(72) Inventors: Rolf SCHIFFERLI, Zofingen (CH); Micha GILOMEN, Zurich (CH); Raeto STADLER, Langnau am Albis (CH)

(21) Appl. No.: 14/597,642

(22) Filed: Jan. 15, 2015

Related U.S. Application Data
(63) Continuation of application No. PCT/EP2013/061509, filed on Jun. 4, 2013.

(30) Foreign Application Priority Data
Jul. 30, 2012 (DE) 20 2012 007 280.3

(51) Int. Cl. H01L 25/11; H02M 7/00

(52) U.S. Cl. CPC H01L 25/117; H02M 7/003
USPC 257/723

(57) ABSTRACT

An exemplary power semiconductor clamping stack includes a plurality of power semiconductor components that are arranged in a row along the stacking direction, and a first and second end plate. The row of power semiconductor components is arranged between the first and second end plate and a clamping force is applied to the first and second end plate in order to tension the row of power semiconductor components between the first and second end plate. A clamping force measuring device is arranged between the first end plate and the row of power semiconductor components in order to adjust the clamping force.

### RELATED APPLICATION(S)

This application is a continuation of International application PCT/EP2013/061509 filed on Jun. 4, 2013, designating the U.S., and claiming priority to German application 202012007280.3 filed in Germany on Jul. 30, 2012. The content of each prior application is hereby incorporated by reference in its entirety.

### FIELD

The present disclosure relates to the field of power electronics, and to a power semiconductor clamping stack used, for example, in current converters.

### BACKGROUND INFORMATION

In known high power water-cooled current converters, a plurality of power semiconductor components are combined in a series circuit with cooling boxes through which water is passed, and at least one DC voltage bus bar element to form a clamping stack. The specified electric and thermal properties are achieved by mechanical tensioning of the clamping stack along the stacking direction between a first and a second end plate through tension rods. So that the power semiconductor clamping stack is always sufficiently tensioned, the power semiconductor clamping stack has at least one spring element. To exchange a faulty power semiconductor component, the clamping stack is relieved of tension.

In known arrangements, GTO (gate turn off) thyristors, IGBTs (insulated gate bipolar transistors), IGCTs (insulated gate controlled thyristors), thyristors or diodes can be used as power semiconductor components.

Known power semiconductor clamping stacks are described in EP 1 178 593 A1 and in DE 196 34 823 A1.

In the case of a power semiconductor clamping stack of the type described in the introduction, it is known that the clamping force between the two end elements cannot be adjusted in a precise manner through the tension rods, since the deflection of the springs used is small and a precise measurement is therefore difficult. However, the precise adjustment of the clamping force of the stack is important, since the stability of the stack is placed at risk if the clamping force is too low and, for example, the power semiconductor components may be damaged if the clamping force is too high.

US 2008/0211157 A1 also discloses a power semiconductor clamping stack, but with merely a single power semiconductor component (US 2008/0211157 A1, for example see FIG. 5, reference sign 92), wherein the power semiconductor clamping stack includes a first and second end plate (reference signs 12, 14) and the single power semiconductor component is arranged between the first and second end plate and a clamping force can be applied to the first and second end plate in order to tension the power semiconductor component between the first and second end plate. In order to adjust the clamping force, a clamping force measuring device (US 2008/0211157 A1 see FIG. 5, reference sign 50) is provided, which is arranged on tension rods (reference sign 20) of the power semiconductor clamping stack.

Furthermore, U.S. Pat. No. 3,688,159 likewise discloses a power semiconductor clamping stack having just a single power semiconductor component (U.S. Pat. No. 3,688,159, for example see FIG. 2, reference sign SCR), wherein the power semiconductor clamping stack includes a first and second end plate (reference signs 42, 16) and the single power semiconductor component is arranged between the first and second end plate, and a clamping force can be applied to the first and second end plate in order to tension the power semiconductor component between the first and second end plate. In order to adjust the clamping force, a clamping force measuring device (U.S. Pat. No. 3,688,159, see FIG. 2 and FIG. 9, reference sign 18) is also provided, which is arranged between the first end plate and a spring unit (reference sign 14, with spring elements 40).

### SUMMARY

A power semiconductor clamping stack including a plurality of power semiconductor components, which are arranged in a row along a stacking direction is disclosed, the clamping stack comprising: a first and second end plate, wherein the row of power semiconductor components is arranged between the first and second end plate such that a clamping force applied to the first and second end plates tensions the row of power semiconductor components between the first and second end plate; a clamping force measuring device is arranged between the first end plate and the row of power semiconductor components to adjust the clamping force, in that the clamping force measuring device includes a spring element, a first element and a second element displaceable along the stacking direction against the spring force of the spring element and against the first element, wherein a length of displacement of the second element against the first element is a measure of a magnitude of the clamping force, wherein the first element has a wedge-shaped channel that extends substantially perpendicularly to the stacking direction, and wherein the second element has a groove that extends substantially perpendicularly to the stacking direction; and a measuring rod is adapted to be guided in the wedge-shaped channel and simultaneously in the groove, wherein an insertion depth of the measuring rod in the wedge-shaped channel correlates to the displacement of the second element against the first element.

### BRIEF DESCRIPTION OF THE DRAWINGS

Objects, advantages, and features of the present disclosure will become clear from the following detailed description of preferred exemplary embodiments of the disclosure in conjunction with the drawings in which:

FIG. 1 shows a power semiconductor clamping stack according to an exemplary embodiment of the disclosure;

FIG. 2 shows a front view in a sectional illustration of a clamping force measuring device of the power semiconductor clamping stack of FIG. 1 according to an exemplary embodiment of the disclosure; and

FIG. 3 shows a three-dimensional illustration of the clamping force measuring device of the power semiconductor clamping stack of FIG. 1 according to an exemplary embodiment of the disclosure.

The reference signs used in the drawing and meaning thereof are listed by way of summary in the list of reference signs. In principle, like parts in the Figures are provided with like reference signs. The described embodiments present the subject matter of the disclosure in an exemplary manner and do not have any limiting effect.

### DETAILED DESCRIPTION

Exemplary embodiments of the present disclosure is therefore to specify a power semiconductor clamping stack in which the clamping force of the stack can be adjusted in a precise manner.

An exemplary power semiconductor clamping stack according to the present disclosure includes a plurality of power semiconductor components, which are arranged in a row along the stacking direction of the stack. The power semiconductor clamping stack also has a first and second end plate, wherein the row of the power semiconductor components is arranged between the first and second end plate and a clamping force can be applied to the first and second end plate in order to tension the row of power semiconductor components between the first and second end plate. In accordance with the disclosure, a clamping force measuring device can be arranged between the first end plate and the row of the power semiconductor components in order to adjust the clamping force. The clamping force of the stack can be adjusted advantageously in a precise manner through the clamping force measuring device.

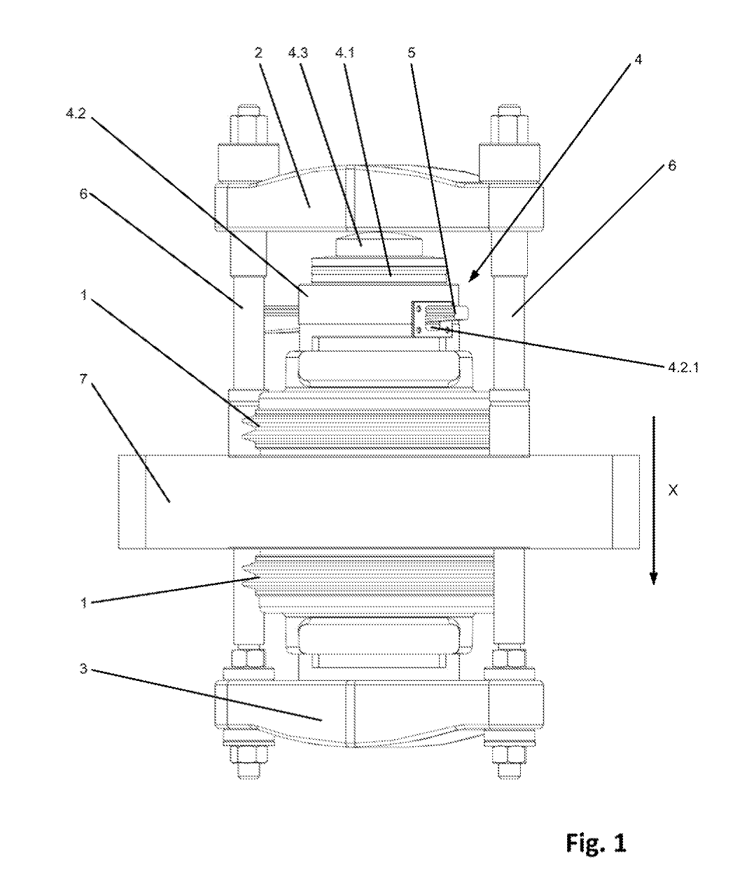

FIG. 1 shows a power semiconductor clamping stack according to an exemplary embodiment of the disclosure. As shown in FIG. 1, the power semiconductor clamping stack includes a plurality of power semiconductor components 1, which are arranged in a row along the stacking direction X of the stack. Furthermore, the power semiconductor clamping stack has a first and second end plate 2, 3, wherein the row of power semiconductor components 1 is arranged between the first and second end plate 2, 3 and a clamping force F can be applied to the first and second end plate 2, 3 in order to tension the row of power semiconductor components 1 between the first and second end plate 2, 3. According to another exemplary embodiment, a bus bar 7, such as a DC voltage bus bar, can be arranged between two power semiconductor components 1, as shown by way of example in FIG. 1. In yet another exemplary embodiment, one or more electric bus bars 7 can also be tensioned in the power semiconductor clamping stack in order to feed the alternating current potential to the power semiconductor components 1. These bus bars can additionally be formed as cooling elements, and the same is true for the DC voltage bus bar. According to the disclosure, a clamping force measuring device 4 is arranged between the first end plate 2 and the row of power semiconductor components 1 in order to adjust the clamping force, through which clamping force measuring device 4 the clamping force F of the stack can be adjusted, advantageously in a precise manner. The clamping force measuring device 4 can remain in the stack arrangement.

The power semiconductor clamping stack according to FIG. 1 includes at least two tension rods 6, which are arranged along the stacking direction X, engage with the first and second end plate 2, 3 and through which the clamping force F can be applied to the first and second end plate 2, 3. As a result, the ends of each tension rod are provided with threads having nuts, through which the clamping force F can then be applied to the two end plates 2, 3 in order to tension the row of power semiconductor components 1 between the end plates 2, 3.

The clamping force measuring device 4 can include an electrically insulating material. According to another exemplary embodiment of the present disclosure, the clamping force measuring device 4 can include an electrically conductive material.

The end plates 2, 3 can include an electrically insulating material or an electrically conductive material.

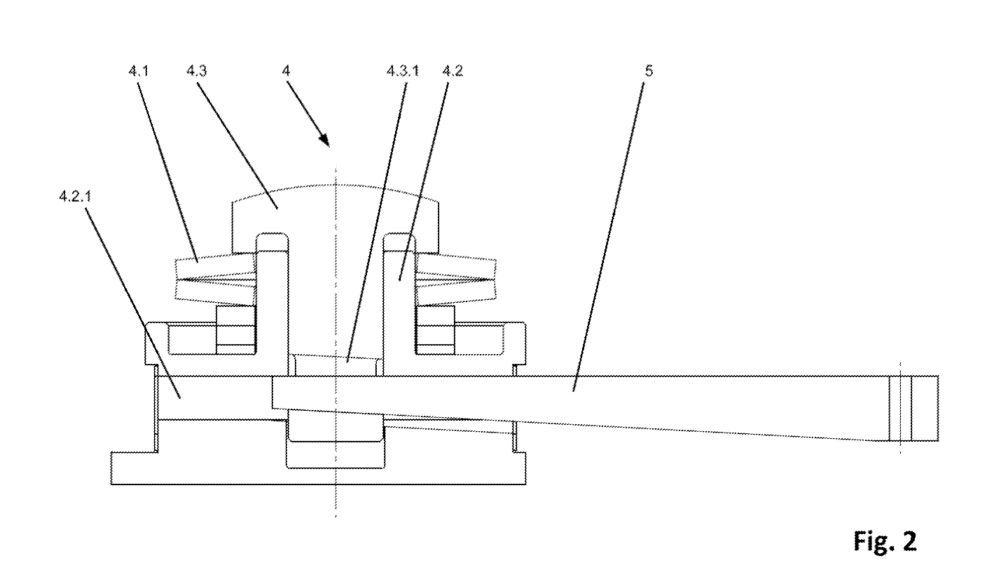

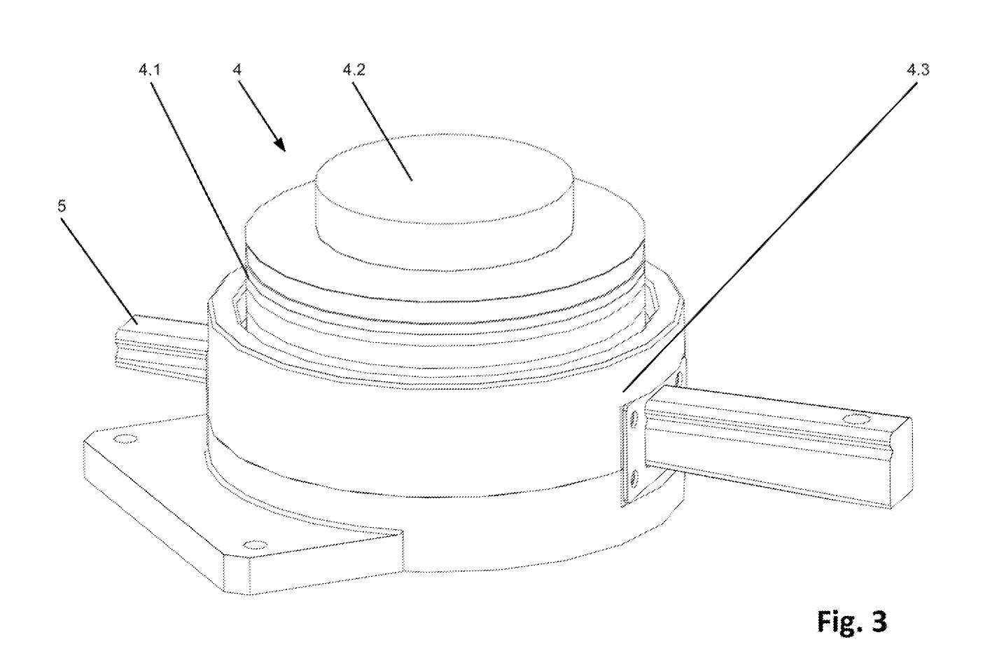

FIG. 2 shows a front view in a sectional illustration of a clamping force measuring device of the power semiconductor clamping stack of FIG. 1 according to an exemplary embodiment of the disclosure. In addition, FIG. 3 shows a three-dimensional illustration of the clamping force measuring device of the power semiconductor clamping stack of FIG. 1 according to an exemplary embodiment of the disclosure.

As shown in FIGS. 2 and 3, the clamping force measuring device 4 has a spring element 4.1, a first element 4.2, and a second element 4.3, which is displaceable along the stacking direction X against the spring force F_{F} of the spring element 4.1 and against the first element 4.2. The length of the displacement of the second element 4.3 against the first element 4.2 is a measure for the magnitude of the clamping force F. As shown in FIG. 1, the first element 4.2 bears against the row of power semiconductor components 1 and the second element 4.3 bears against the first end plate 2. The clamping force measuring device 4 optionally can also be mounted the other way round in the power semiconductor clamping stack. As shown in FIG. 2, The surface of the second element 4.3, which bears against the first end plate 2, can be formed in the manner of a spherical cap. The first end plate 2, thus advantageously bears (e.g., frequently or always) against the second element 4.3 in for clamping force transfer.

In accordance with FIG. 2 the first element 4.2 has a wedge-shaped channel 4.2.1, which extends substantially perpendicularly to the stacking direction X. Furthermore, the second element 4.3 has a groove 4.3.1, which extends substantially perpendicularly to the stacking direction X. In addition, a measuring rod 5 is guided in the wedge-shaped channel 4.2.1 and simultaneously in the groove 4.3.1. The insertion depth of the measuring rod 5 in the wedge-shaped channel 4.2.1 correlates with the displacement of the second element 4.3 against the first element 4.2. The measuring rod 5 can likewise wedge-shaped.

To adjust the clamping force F, the nuts of the tension rods 6 are first tightened, such that the first and second end plate 2, 3 presses onto the row of power semiconductor components 1 and the clamping force measuring device 4. Here, the second element 4.3 is displaced along the stacking direction X against the spring force F_{F} of the spring element 4.1 and against the first element 4.2. According to another embodiment of the present disclosure, a hydraulic bias toward the two end plates 2, 3 with subsequent tightening of the nuts can be used. By inserting the measuring rod 5 into the wedge-shaped channel 4.2.1 and into the groove 4.3.1 until a resistance is experienced, it is possible to determine in a very precise manner how high the clamping force F already is and whether the clamping force should be increased or reduced at all for a desired target value. The above-mentioned resistance therefore results from the fact that the second element 4.3 is displaced only by a certain length against the first element 4.2, and the groove 4.3.2 thus displaced limits the insertion depth of the measuring rod 5 in the wedge-shaped channel 4.2.1. In order to read (e.g., visually) the clamping force F, the measuring rod 5 can have a scale provided thereon. Since the insertion depth of the measuring rod 5 in the wedge-shaped channel 4.2.1 correlates with the displacement of the second element 4.3 against the first element 4.2, and since the length of the displacement of the second element 4.3 against the first element 4.2 is a measure for the magnitude of the clamping force F, a very precise determination and adjustment of the clamping force F is possible via the clamping force measuring device 4 of the power semiconductor clamping stack.

A bias of the clamping force measuring device 4 can also be implemented outside the power semiconductor clamping stack by compressing the clamping force measuring device 4, for example hydraulically, to the desired force, either by reading (e.g., visually) at the measuring rod 5 or by an external force measuring device. The measuring rod 5 is then used to hold the compressed position. In the case of mounting in the power semiconductor clamping stack, the clamping force measuring device 4 is compressed. As soon as the measuring rod 5 can be removed from the clamping force measuring device 4, the pre-set force is transferred to the power semiconductor clamping stack.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE SIGNS

1 power semiconductor component
2 first end plate
3 second end plate
4 clamping force measuring device
4.1 spring element
4.2 first element
4.2.1 wedge-shaped channel
4.3.1 groove
4.3 second element
5 measuring rod
6 tension rod
7 bus bar

What is claimed is:

1. A power semiconductor clamping stack including a plurality of power semiconductor components, which are arranged in a row along a stacking direction, the clamping stack comprising:
a first and a second end plate, wherein the row of power semiconductor components is arranged between the first and second end plate such that a clamping force applied to the first and second end plates tensions the row of power semiconductor components between the first and second end plate;
a clamping force measuring device is arranged between the first end plate and the row of power semiconductor components to adjust the clamping force, wherein the clamping force measuring device includes a spring element, a first element, and a second element displaceable along the stacking direction against the spring force of the spring element and against the first element, wherein a length of displacement of the second element against the first element is a measure of a magnitude of the clamping force, wherein the first element has a wedge-shaped channel that extends substantially perpendicularly to the stacking direction, and wherein the second element has a groove that extends substantially perpendicularly to the stacking direction; and
a measuring rod is adapted to be guided in the wedge-shaped channel and simultaneously in the groove, wherein an insertion depth of the measuring rod in the wedge-shaped channel correlates to the displacement of the second element against the first element.

2. The power semiconductor clamping stack as claimed in claim 1, wherein the first element bears against the row of power semiconductor components and the second element bears against the first end plate.

3. The power semiconductor clamping stack as claimed in claim 2, wherein a surface of the second element bearing against the first end plate is a spherical cap.

4. The power semiconductor clamping stack as claimed in claim 1, comprising:
at least two tension rods arranged along the stacking direction and engage the first and second end plate, whereby the clamping force is applied to the first and second end plate.

5. The power semiconductor clamping stack as claimed in claim 2, comprising:
at least two tension rods arranged along the stacking direction and engage the first and second end plate, whereby the clamping force is applied to the first and second end plate.

6. The power semiconductor clamping stack as claimed in claim 3, comprising:
at least two tension rods arranged along the stacking direction and engage the first and second end plate, whereby the clamping force is applied to the first and second end plate.

7. The power semiconductor clamping stack as claimed in claim 1, wherein the clamping force measuring device includes an electrically insulating material.

8. The power semiconductor clamping stack as claimed in claim 2, wherein the clamping force measuring device includes an electrically insulating material.

9. The power semiconductor clamping stack as claimed in claim 3, wherein the clamping force, measuring device includes an electrically insulating material.

10. The power semiconductor clamping stack as claimed in claim 4, wherein the clamping force measuring device includes an electrically insulating material.

11. The power semiconductor clamping stack as claimed in claim 1, wherein the clamping force measuring device includes an electrically conductive material.

12. The power semiconductor clamping stack as claimed in claim 2, wherein the clamping force measuring device includes an electrically conductive material.

13. The power semiconductor clamping stack as claimed in claim 3, wherein the clamping force measuring device includes an electrically conductive material.

14. The power semiconductor clamping stack as claimed in claim 4, wherein the clamping force measuring device includes an electrically conductive material.

15. The power semiconductor clamping stack as claimed in claim 1, wherein the first and second end plate include an electrically insulating material.

16. The power semiconductor clamping stack as claimed in claim 2, wherein the first and second end plate include an electrically insulating material.

17. The power semiconductor clamping stack as claimed in claim 3, wherein the first and second end plate include an electrically insulating material.

18. The power semiconductor clamping stack as claimed claim 1, wherein the first and second end plate include an electrically conductive material.

19. The power semiconductor clamping stack as claimed claim 2, wherein the first and second end plate include an electrically conductive material.

20. The power semiconductor clamping stack as claimed claim 3, wherein the first and second end plate include an electrically conductive material.
